(19) United States
(12) Patent Application Publication
(10) Pub. No.: US 2026/0155811 A1
(43) Pub. Date: Jun. 4, 2026

(54) CLOCK MODULATION CIRCUIT AND CLOCK MODULATION METHOD

(71) Applicants: Kabushiki Kaisha Toshiba, Kawasaki-shi (JP); Toshiba Electronic Devices & Storage Corporation, Kawasaki-shi (JP)

(72) Inventors: Shinji HIROKAWA, Kawasaki Kanagawa (JP); Tetsuya NAKAMURA, Yokohama Kanagawa (JP)

(21) Appl. No.: 19/310,859

(22) Filed: Aug. 26, 2025

(30) Foreign Application Priority Data
Nov. 29, 2024 (JP) 2024-207872

(51) Int. Cl. H03K 5/00; H03K 21/08

(52) U.S. Cl. CPC H03K 5/00006; H03K 21/08

(57) ABSTRACT

According to one embodiment, a clock modulation circuit includes a clock output circuit that outputs a clock signal and a multi-divider circuit that has a plurality of frequency division circuits to which the clock signal from the clock output circuit is input. Each frequency division circuit is configured to frequency divide the clock signal. A frequency division control circuit is configured to control a frequency division start time for each of the frequency division circuits and control a phase difference between output signals of at least one pair of frequency division circuits in the plurality of frequency division circuits based on a period of the clock signal.

### CROSS-REFERENCE TO RELATED APPLICATION(S)

This application is based upon and claims the benefit of priority from Japanese Patent Application No. 2024-207872, filed Nov. 29, 2024, the entire contents of which are incorporated herein by reference.

### FIELD

Embodiments described herein relate generally to a clock modulation circuit and a clock modulation method.

### BACKGROUND

A clock having a frequency on the order of gigahertz (GHz) may be mounted in a chip such as a microcontroller unit (MCU) or a micro processing unit (MPU). Since characteristics of the clock affect performance of the chip, it is desired to measure the characteristics of the clock (such as Jitter or Duty cycle). When off-chip measurement is performed on the clock, the frequency may be too high for an external circuit outside the chip to measure the clock characteristics when the on-chip frequency is high.

### BRIEF DESCRIPTION OF THE DRAWINGS

FIG. 1 is a block diagram illustrating a clock modulation circuit according to a first embodiment.

FIG. 2 is an example of a circuit configuration of a clock modulation circuit according to a first embodiment.

FIG. 3A is an example of a circuit configuration of a frequency division control circuit of a clock modulation circuit according to a first embodiment.

FIG. 3B is an example of another circuit configuration of a frequency division control circuit of a clock modulation circuit according to a first embodiment.

FIG. 4 is a timing chart of an operation of a frequency division control circuit.

FIG. 5 is a timing chart of an operation of a clock modulation circuit according to a first embodiment.

FIG. 6 is a flowchart of another operation of a clock modulation circuit according to a first embodiment.

FIG. 7 is a flowchart of an operation of a clock modulation circuit according to a first modification example of a first embodiment.

FIG. 8A depicts aspects related to an example of a statistical process of a clock modulation circuit according to a first modification example of a first embodiment.

FIG. 8B depicts aspects related to an example of another statistical process of a clock modulation circuit according to a first modification example of a first embodiment.

FIG. 9 is a timing chart of an operation of a clock modulation circuit according to a first modification example of the first embodiment.

FIG. 10 is an example of a circuit configuration of a clock modulation circuit according to a second embodiment.

FIG. 11 is a timing chart of an operation of the clock modulation circuit according to a second embodiment.

FIG. 12 is an example of a circuit configuration of a clock modulation circuit according to a third embodiment.

FIG. 13 is a timing chart of an operation of a clock modulation circuit according to a third embodiment.

FIG. 14 is an example of a circuit configuration of a clock modulation circuit according to a fourth embodiment.

FIG. 15 is an example of a circuit configuration of a select circuit of a clock modulation circuit according to a fourth embodiment.

FIG. 16 is an example of a circuit configuration of a clock modulation circuit according to a modification example of a fourth embodiment.

FIG. 17 is an example of a circuit configuration of a clock modulation circuit according to a fifth embodiment.

FIG. 18 is a timing chart of an operation of a clock modulation circuit according to a fifth embodiment.

FIG. 19 is a timing chart of another operation of a clock modulation circuit according to a fifth embodiment.

### DETAILED DESCRIPTION

Embodiments provide a clock modulation circuit and a clock modulation method that can measure a characteristic of a clock signal with higher accuracy.

In general, according to one embodiment, there is provided a clock modulation circuit including a clock output circuit, a multi-divider circuit that has a plurality of frequency division circuits to which a clock signal is input from the clock output circuit and which frequency divides the clock signal, and a frequency division control circuit that controls a start time of frequency division of each of the plurality of frequency division circuits. The frequency division control circuit also controls a phase difference between at least one pair of output signals of the plurality of frequency division circuits based on a period of the clock.

In general, according to another embodiment, a clock modulation method for a clock modulation circuit includes: transmitting a first frequency division start signal from a frequency division control circuit to a first frequency division circuit that frequency divides a clock signal; outputting a first output signal from the first frequency division circuit, the first output signal being a frequency divided clock signal; transmitting a second frequency division start signal from the frequency division control circuit to a second frequency division circuit that frequency divides the clock signal; and outputting a second output signal from the second frequency division circuit, the second output signal being a frequency divided clock signal.

Hereinafter, certain example embodiments of the present disclosure will be described with reference to the drawings.

The drawings are schematic or conceptual, and the relationship between the dimensions, such as thickness and width, of each portion, the ratio of the sizes between the portions, and the like are not always the same as the actual ones. Even when the same portion being represented, the dimensions and proportions of such may be represented differently depending on the drawing.

In the following, an H-state refers to a signal or voltage state having a high-level voltage of, for example, 5 volts (V) in a digital (binary) signal that swings between 0 volts (V) and 5 volts (V). Correspondingly, an L-state refers to a signal or voltage state having a low-level voltage of, for example, 0 V.

In this specification and corresponding drawings, when the same element or aspect is depicted in multiple drawings, an initial description may be provided for the element or aspect in conjunction with one drawing and repetitive description of the element or aspect may be omitted from discussion of a subsequent drawing. The elements (or aspects) will be designated by the same reference symbols across the different drawings when such elements (or aspects) are the same or substantially so, and additional description thereof may be omitted as appropriate.

### First Embodiment

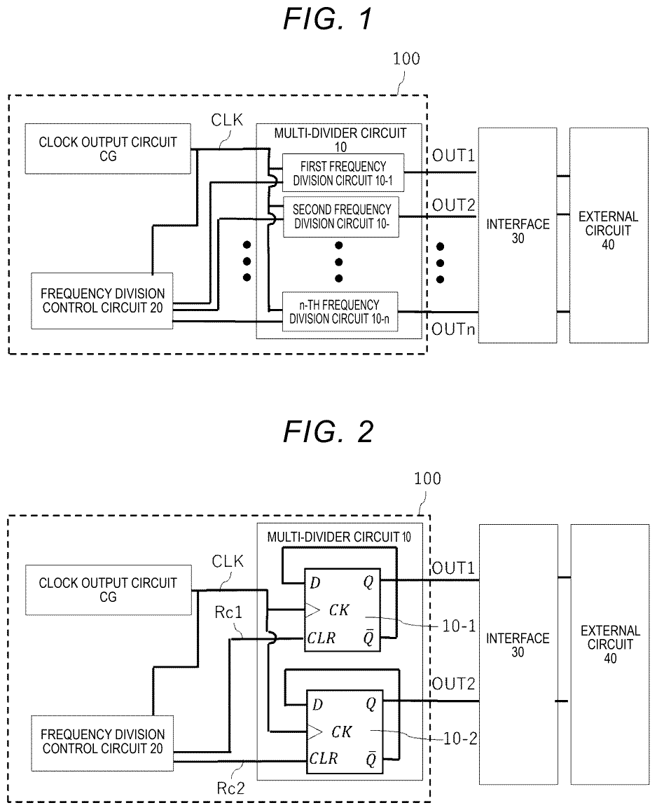

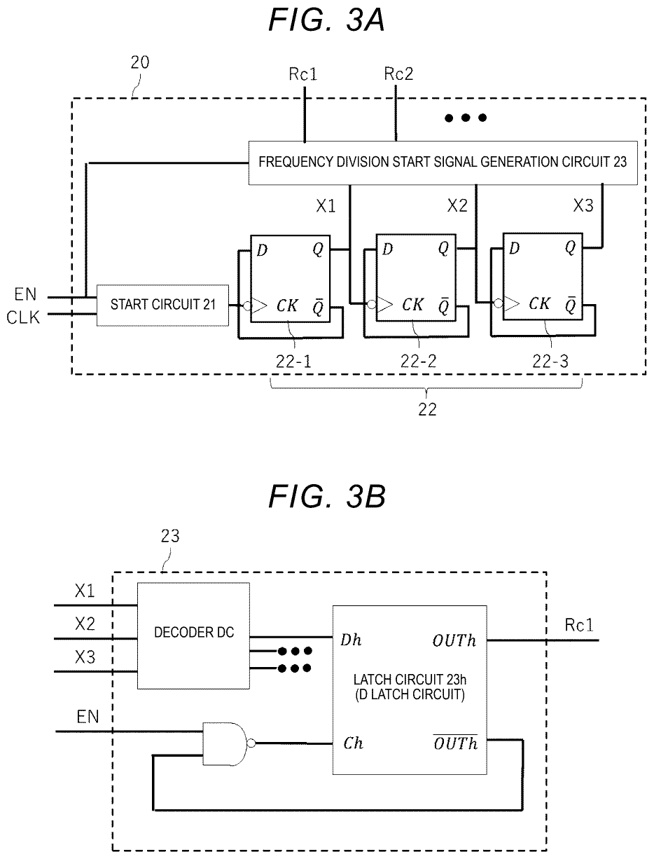

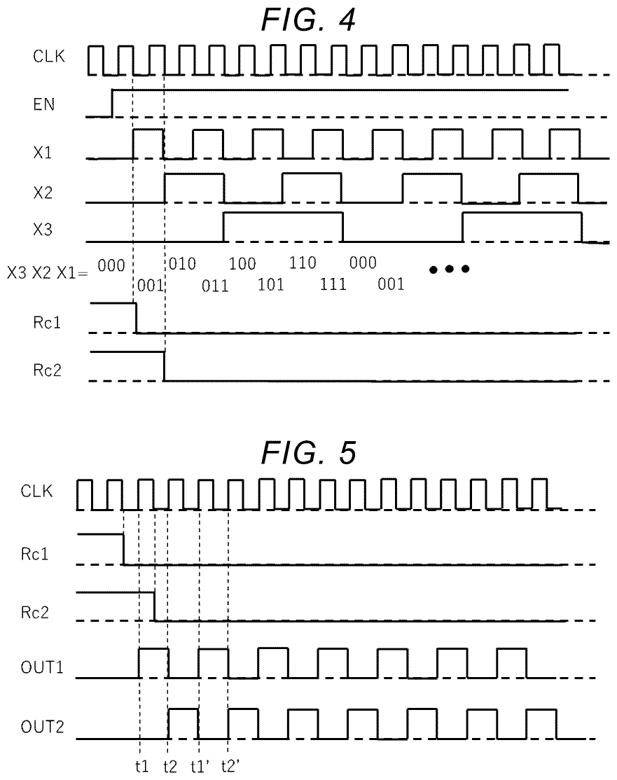

FIG. 1 is a block diagram of a clock modulation circuit 100 according to a first embodiment. FIG. 2 illustrates an example of a circuit configuration of the clock modulation circuit 100 according to the first embodiment. FIGS. 3A and 3B are examples of a circuit configuration of a frequency division control circuit 20 of the clock modulation circuit 100 according to the first embodiment. FIG. 4 is a timing chart illustrating an example of an operation of the clock modulation circuit 100 according to the first embodiment. FIG. 5 is a flowchart illustrating the example of the operation of the clock modulation circuit 100 according to the first embodiment. In the following, the concept of “Jitter” should be considered to include any “Skew” caused by a difference in signal transmission path and/or a fluctuation of a signal caused by the circuit configuration of the clock modulation circuit 100. The present example is a configuration that facilitates measurement of Jitter. Details will be described with reference to FIG. 5.

As illustrated in FIG. 1, the clock modulation circuit 100 includes a clock output circuit CG, a multi-divider circuit 10 connected to the clock output circuit CG, and a frequency division control circuit 20 that is connected to the clock output circuit CG and controls an operation of the multi-divider circuit 10. An external circuit 40 (e.g., a measurement circuit) receives output signals OUT1, OUT2, . . . and OUTn from the multi-divider circuit 10 via the interface 30 and measures these output signals.

The components of clock modulation circuit 100 can be formed on the same chip, for example. The clock modulation circuit 100 mounted in or with an MCU or the like. The interface 30 transmits signals from the clock modulation circuit 100 to the external circuit 40. The clock modulation circuit 100 and the external circuit 40 may have different operation voltages, for example. The interface 30 is, for example, a general-purpose input and output (I/O) interface. The external circuit 40 receives a signal from the interface 30, and measures a waveform of the signal. The external circuit 40 can measure a time change of a voltage of the signal, and may include, for example, an oscilloscope.

The clock output circuit CG outputs, for example, a clock CLK (clock signal) having a frequency from several MHz range up to the GHz range. The clock output circuit CG may include a circuit that generates the clock CLK.

The multi-divider circuit 10 has at least two frequency division circuits (designated a first frequency division circuit 10-1, a second frequency division circuit 10-2, . . . and an n-th frequency division circuit 10-n, where n is a natural number of 2 or more). An output signal of the clock output circuit CG is input to the frequency division circuits, and a frequency-divided signal is respectively output as output signals OUT1, OUT2, . . . and OUTn. The first frequency division circuit 10-1 and the second frequency division circuit 10-2 are connected to the clock output circuit CG in parallel in this example.

Here, “frequency division” is a modulation that reduces a frequency of a signal. For example, when a frequency division by 2 is performed, the frequency of a signal is decreased to ½ of the original frequency. In the same manner, when a frequency division by n is performed, the frequency of the signal is reduced to 1/n of the original frequency. When a frequency division circuit provided in the multi-divider circuit 10 is a circuit that performs frequency division by n, the multi-divider circuit 10 is preferably provided with at least n frequency division circuits.

The frequency division control circuit 20 receives the clock CLK from the clock output circuit CG, and controls a start of a frequency division operation by each of the first frequency division circuit 10-1, the second frequency division circuit 10-2, . . . and the n-th frequency division circuit 10-n. Start times for frequency division by the first frequency division circuit 10-1, the second frequency division circuit 10-2, . . . and the n-th frequency division circuit 10-n may be offset from each other by a period (reciprocal of the frequency) of the clock CLK output by the clock output circuit CG, or the start times of frequency division may be simultaneous. In present context, when it is said that the times are simultaneous, the times will have a time difference of ¼ or less of the period of the clock CLK as output by the clock output circuit CG. When it is said that the times are simultaneous, the times may have a time difference of ⅛ or less of the period of the clock CLK, or a time difference of 1/16 or less. In other words, when it is said that lengths of the times are the same, this includes cases in which the time difference is within ¼ or less of the period of the clock CLK. When it is said that the start times of frequency division of the first frequency division circuit 10-1 and the second frequency division circuit 10-2 deviate by a period of the clock CLK, an absolute value of a time difference between the frequency division start for the first frequency division circuit 10-1 and the second frequency division circuit 10-2 can be, for example, between ¾ and 5/4 of the period of the clock CLK. The frequency division control circuit 20 controls a phase difference between at least one pair of output signals from the plurality of frequency division circuits based on a period of a clock.

Next, an operation of the clock modulation circuit 100 will be described.

First, the clock CLK is output from the clock output circuit CG. The clock CLK is input to the first frequency division circuit 10-1, the second frequency division circuit 10-2, . . . and the n-th frequency division circuit 10-n. But, at this time, at the beginning, the first frequency division circuit 10-1, the second frequency division circuit 10-2, . . . and the n-th frequency division circuit 10-n do not perform a frequency division operation. The first frequency division circuit 10-1, the second frequency division circuit 10-2, . . . and the n-th frequency division circuit 10-n may in fact perform the frequency division operation, but the start time of the frequency division operation is not necessarily controlled at this point, as will be described with reference to FIG. 5.

Next, the frequency division control circuit 20 starts an operation. The frequency division control circuit 20 starts the frequency division operation of the first frequency division circuit 10-1, the second frequency division circuit 10-2, . . . and the n-th frequency division circuit 10-n based on an input of the clock CLK thereto. For example, in a mode (FIG. 5) of performing an operation of shifting a start time of the frequency division for each of the first frequency division circuit 10-1, the second frequency division circuit 10-2, . . . and the n-th frequency division circuit 10-n by a period of the clock CLK, the frequency division control circuit 20 controls the plurality of frequency division circuits to start the frequency division in order (in sequence).

The clock CLK is converted into the output signals OUT1, OUT2, . . . and OUTn, each of which has been frequency-divided in the multi-divider circuit 10. Frequencies of the output signals OUT1, OUT2, . . . and OUTn are lower than the frequency of the clock CLK. The output signals OUT1, OUT2, . . . and OUTn are input to the external circuit 40 via the interface 30, and the signal waveforms thereof are measured. Various characteristics of the clock CLK can be calculated from the measurement result of the external circuit 40.

Even when the clock CLK has a high-speed (that is, the frequency is high), a signal which has a frequency that has been decreased by the multi-divider circuit 10 can be input to the interface 30 and the external circuit 40. For example, even when an operation voltage of the interface 30 is higher than an operation voltage of the clock modulation circuit 100 and it is difficult to output a high frequency signal, the frequency of the signal can be reduced such that the characteristics of the signal can be measured in the external circuit 40.

FIG. 2 is an example in which the multi-divider circuit 10 has two frequency division circuits that each perform frequency division by 2. An example of a circuit configuration in which a frequency division circuit is implemented as a flip-flop (flip-flop circuit) will be described, but the present disclosure is not limited thereto.

First, designation of each terminal of a D flip-flop with reset illustrated in FIG. 2 will be described. The terminal D is a data input terminal. The terminal CK is a clock input terminal. For example, a state (H-state or L-state) input to the data input terminal D at a rising edge time of a clock signal input to the clock input terminal CK is output from the output terminal Q. A signal that is inverted from the output terminal Q signal, is output from an inversion output terminal Q* (in specification text, the symbol “Q*” corresponds to the symbol Q̅ (Q-bar) used in the drawings).

A clear terminal CLR is a terminal to which a signal for controlling a start of an operation of the flip-flop can be input. For example, while a signal in an L-state is input to the clear terminal CLR, the input from the clock input terminal CK is accepted, and while a signal in an H-state is input to the clear terminal CLR, the input from the clock input terminal CK is not accepted.

The inversion output terminal Q* and the data input terminal D of the flip-flop described above can be connected to each other to form a frequency division circuit for frequency division by 2. The output terminal Q of the first frequency division circuit 10-1 outputs the output signal OUT1. A state of the output signal OUT1 is inverted at a rising edge time of the clock CLK input to the clock input terminal CK.

A start time of frequency division of the first frequency division circuit 10-1 is controlled by a first frequency division start signal Rc1 from the frequency division control circuit 20. A start time of frequency division of the second frequency division circuit 10-2 is controlled by a second frequency division start signal Rc2 from the frequency division control circuit 20.

Next, an example of a circuit configuration of the frequency division control circuit 20 will be described with reference to FIG. 3A. The frequency division control circuit 20 includes a start circuit 21, a bit sequence generation circuit 22, and a frequency division start signal generation circuit 23. The frequency division control circuit 20 illustrated in FIG. 3A receives a start signal EN. The start signal EN is not specifically illustrated in FIG. 1. The start signal EN is a signal for controlling a start of an operation of the frequency division control circuit 20. The start circuit 21 inputs the clock CLK to the bit sequence generation circuit 22 while the start signal EN is, for example, in an H-state. The start signal EN controls turning-on and turning-off of the frequency division control circuit 20.

The bit sequence generation circuit 22 receives an input of the clock CLK and outputs a first bit signal X1, a second bit signal X2, and a third bit signal X3. The bit sequence generation circuit 22 may have a total of m outputs satisfying the relationship n≤2^{m}−1, where n is the number of frequency division circuits provided in the multi-divider circuit 10. That is, the bit sequence generation circuit 22 provides the first bit signal X1, the second bit signal X2, . . . and the m-th bit signal Xm as outputs. FIG. 3A illustrates three D flip-flops 22-1, 22-2, and 22-3, but the number of D flip-flops can be any number m satisfying n≤2^{m}−1 for the n frequency division circuits provided in the multi-divider circuit 10.

A clock inversion signal can be input to the clock input terminal CK of the D flip-flop illustrated in FIG. 3A, but this is an example when a falling edge of the clock CLK is a trigger of the frequency division start signals Rc1, Rc2, etc., but examples are not necessarily limited thereto.

The frequency division start signal generation circuit 23 receives the first bit signal X1, the second bit signal X2, etc., and outputs frequency division start signals (first frequency division start signal Rc1, second frequency division start signal Rc2, etc.). The frequency division start signal generation circuit 23 converts the m-bit inputs of the first bit signal X1, the second bit signal X2, . . . and the m-th bit signal Xm into 2^{m}−1 different frequency division start signals. In the example illustrated in FIG. 3A, the frequency division start signal generation circuit 23 provides a 3-input, 8-output decoder (for example, a decoder DC illustrated in FIG. 3B). That is, a 3-bit signal (X1, X2, and X3) representing binary numbers is input to the frequency division start signal generation circuit 23, and 8 codes corresponding to decimal numbers are output from the frequency division start signal generation circuit 23.

The operation of the frequency division control circuit 20 illustrated in FIG. 3A will be further described with reference to the timing chart in FIG. 4. First, the start signal EN is shifted to an H-state, and the clock CLK is thus input to the bit sequence generation circuit 22, so operation of the frequency division control circuit 20 is started (begins).

The D flip-flop 22-1 outputs the first bit signal X1 triggered by a falling edge of the clock CLK. The first bit signal X1 is a signal obtained by frequency dividing the clock CLK by 2.

The D flip-flop 22-2 (to which the first bit signal X1 is input to the clock input terminal CK) outputs the second bit signal X2 triggered by a falling edge of the first bit signal X1. The second bit signal X2 is a signal obtained by frequency dividing the clock CLK by 4.

The D flip-flop 22-3 (to which the second bit signal X2 is input to the clock input terminal CK) outputs the third bit signal X3 triggered by a falling edge of the second bit signal X2. The third bit signal X3 is a signal obtained by frequency dividing the clock CLK by 8.

An H-state and an L-state of the first bit signal X1, the second bit signal X2, and the third bit signal X3 can be regarded as binary data, and can thus be regarded as information of a total of 3 bits. A bit sequence (X3 X2 X1) in which the first bit signal X1, the second bit signal X2, and the third bit signal X3 are arranged is represented as binary values in FIG. 4. For example, when only the first bit signal X1 is in an H-state, the bit sequence value corresponds to 001.

The bit sequence (X3 X2 X1) starts from 000 and then changes to 001, 010, 011, 100, 101, 110, 111, 000, 001, . . . at every half period of the clock CLK. That is, the bit sequence sequentially is shifted from 0 to 2³−1 in 8 codes in binary.

As illustrated in FIGS. 3A and 4, when including the three bit signals of the first bit signal X1, the second bit signal X2, and the third bit signal X3, it is possible to select a trigger from 7 codes (other than 000 as an initial state) as the frequency division start signals.

In FIG. 4, the first frequency division start signal Rc1 is shifted to an L-state as a trigger when the bit sequence (X3 X2 X1) is in a state of 001. For the rest of the bit sequences, the state is latched. The second frequency division start signal Rc2 is shifted to an L-state as a trigger when the bit sequence (X3 X2 X1) is in a state of 010. For the rest of the bit sequences, the state is latched.

In the same manner, a shift time of each frequency division start signal to the L-state can be controlled by shifting the third frequency division start signal Rc3 to the L-state by using 011 as a trigger and shifting the fourth frequency division start signal Rc4 to the L-state by using 100 as a trigger in sequence.

An example of a configuration in which the first frequency division start signal Rc1 latches a state for a bit sequence other than the bit sequence (X3 X2 X1) of 001 will be described with reference to FIG. 3B.

The frequency division start signal generation circuit 23 includes a latch circuit 23h (for example, a D latch circuit) in addition to the decoder DC. The D latch circuit has a data input terminal Dh, a control input terminal Ch, an output terminal OUTh, and an inversion output terminal OUTh* (OUTh-bar in drawing). While a signal in an H-state is input to the control input terminal Ch, a signal input to the data input terminal Dh is output from the output terminal OUTh. The output is latched while the signal in an L-state is input to the control input terminal Ch. The output of the decoder DC is input to the data input terminal Dh of the D latch circuit. The first frequency division start signal Rc1 is output from the output terminal OUTh of the D latch circuit. The input signal to the control input terminal Ch is determined based on an inversion output signal of the inversion output terminal OUTh* of the D latch circuit.

When the bit sequence (X3 X2 X1) is, for example, 001, the output from the decoder DC to the data input terminal Dh is changed, and the output signal of the D latch circuit is in an L-state (that is, the first frequency division start signal Rc1 is in an L-state). At this time, the inversion output signal of the D latch circuit is in an H-state. The inversion output signal of the inversion output terminal OUTh* is fed back to the control input terminal Ch. For example, a NAND gate output of the start signal EN and the inversion output signal OUTh* is input to the control input terminal Ch. That is, while the start signal EN is in an H-state (that is, the frequency division control circuit 20 is operating), a signal in the L-state is input to the control input terminal Ch after the first frequency division start signal Rc1 is shifted to an L-state, and the state of the first frequency division start signal Rc1 is latched. The state of the first frequency division start signal Rc1 is not latched while the start signal EN is in an L-state (that is, the frequency division control circuit 20 is not operating).

The configuration in which the inversion output signal OUTh* is fed back to the control input terminal Ch may have additional configuration including, for example, a select circuit or the like in conjunction with the NAND circuit. Although the example in which the frequency division start signal generation circuit 23 has the D latch circuit is described, the frequency division start signal generation circuit 23 may be replaced with another circuit as long as the circuit has a configuration for latching a signal state.

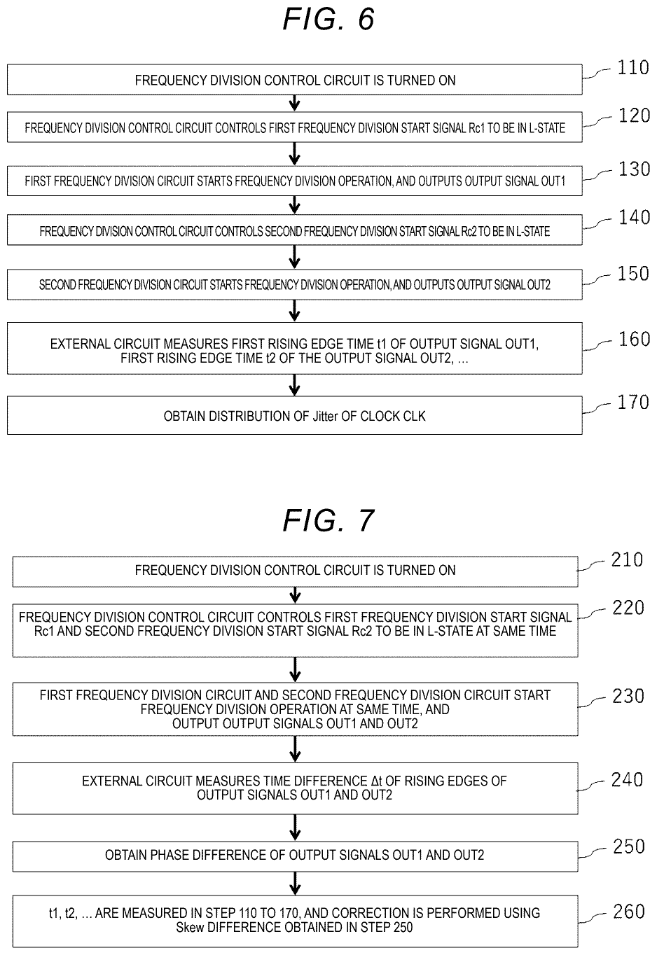

The operation of the clock modulation circuit 100 will be further described with reference to the timing chart in FIG. 5 and the flowchart in FIG. 6.

The timing chart in FIG. 5 illustrates a time change of the clock CLK signal illustrated in FIG. 2, the first frequency division start signal Rc1, the second frequency division start signal Rc2, and the output signals OUT1 and OUT2.

First, the frequency division control circuit 20 generates a frequency division start signal by using, for example, the configuration illustrated in FIG. 3. As illustrated in FIG. 4, times of falling edge of the first frequency division start signal Rc1 and the second frequency division start signal Rc2 deviate by a period of the clock CLK.

Next, with reference to FIG. 2 again, when the first frequency division start signal Rc1 input to the clear terminal CLR in an L-state and a rising edge signal of the clock CLK is input to the clock input terminal CK, the output signal OUT1 level is changed. At a time t1 illustrated in FIG. 5, the output signal OUT1 is shifted from an L-state to an H-state. The output signal OUT1 is shifted back to the L-state again at a time t2 when the next rising edge of the clock CLK is received.

Since the falling edge time of the second frequency division start signal Rc2 is delayed (offset) from the first frequency division start signal Rc1 by a period of the clock CLK, the output signal OUT2 is shifted to an H-state at a time that is delayed (offset) by the period of the clock CLK from the time at which the output signal OUT1 is shifted to the H-state. The output signal OUT2 is shifted to an H-state at the time t2. The output signal OUT2 is shifted back to the L-state again at a time t3 when the next rising edge of the clock CLK is received.

That is, the output signal OUT1 and the output signal OUT2 are signals obtained by performing frequency division by 2 on the clock CLK signal, but the times of the rising edge and the falling edge may deviate by a period of the clock CLK. In other words, phases of the output signal OUT1 and the output signal OUT2 deviate from each other by the period of the clock CLK.

FIG. 4 depicts an example in which the output signals OUT1 and OUT2 levels change (shift) at a rising edge time of the clock CLK, but in this case, it may be desirable that the frequency division start signal is triggered by the falling edge of the clock CLK. A margin of one-half the period of the clock CLK until a next rising edge of the clock CLK arrives after the frequency division start signal is shifted to an L-state, and the rising edge times of the output signals OUT1 and OUT2 can be more reliably controlled.

Next, a flowchart illustrated in FIG. 6 illustrates an example of a process of measuring characteristics of the clock CLK by using the clock modulation circuit 100 according to the present embodiment. The flow illustrated in FIG. 6 is an example for measuring Jitter of the clock CLK. The present embodiment will be described with reference to FIG. 2 as appropriate.

First, in step S110, the frequency division control circuit 20 is turned on and starts an operation. Here, the turning on is not limited to a case where the frequency division control circuit 20 is shifted from an off-state to an on-state, but also includes a case where the frequency division control circuit 20 is shifted from the on-state to the off-state once and then is shifted to the on-state. For example, the frequency division control circuit 20 is turned on in synchronization with a time at which the measurement of the clock CLK is started.

In the subsequent step S120, the frequency division control circuit 20 shifts the first frequency division start signal Rc1 to an L-state.

In step S130, when the first frequency division start signal Rc1 is in an L-state, the first frequency division circuit 10-1 performs a frequency division operation to output the output signal OUT1.

In step S140, the frequency division control circuit 20 shifts the second frequency division start signal Rc2 to an L-state. The ordering of step S130 and step S140 is not limited to the order illustrated in FIG. 5.

In step S150, when the second frequency division start signal Rc2 is in an L-state, the second frequency division circuit 10-2 performs a frequency division operation to output an output signal OUT2. A phase of the output signal OUT2 may be delayed by a period of the clock CLK with respect to the output signal OUT1.

The output signals OUT1 and OUT2 are transmitted to the external circuit 40 via the interface 30. In step S160, the external circuit 40 measures the characteristics of the output signals OUT1 and OUT2 (signals divided and thus reduced in frequency).

With reference to FIG. 5, the first rising edge time t1 of the output signal OUT1 is measured. The first rising edge time t2 of the output signal OUT2 is also measured. Subsequently, a second rising edge time t1′ of the output signal OUT1 is measured, a second rising edge time t2′ of the output signal OUT2 is measured, and this measuring of rising edge times for each output signal (OUT1, OUT2) can be repeated, and thus each rising edge time t1, t2, t1′, t2′, etc. of the clock CLK signal can be obtained from the combination of repeated measurements for output signals OUT1, OUT2.

For example, the time t2 is obtained by using the time t1 as a reference (time zero) and then calculated backwards from a known frequency (or a period) of the clock CLK, so that it is possible to evaluate the extent to which the time t2 deviates from an ideal case where Jitter is zero. For example, the time t2′ is obtained by using the time t1′ as a reference (time zero) and calculated backwards from a known frequency (or a period) of clock CLK, so that the extent to which the time t2′ deviates from an ideal case where Jitter is zero can be evaluated. Jitter amount can be one of the characteristics of the clock CLK, and may be evaluated as described above (step S170). Specifically, t2-t1 can be calculated and the known period of the clock CLK subtracted, and set as one data point for evaluating Jitter.

The flow in FIG. 6 is substantially the same even when n (the total number of frequency division circuits) is 3 or more in FIG. 2.

When n is 3 or more, the frequency division control circuit 20 eventually shifts an n-th frequency division start signal Rcn to an L-state. When the n-th frequency division start signal Rcn is in the L-state, the n-th frequency division circuit 10-n performs a frequency division operation to output the output signal OUTn. Phases of the output signal OUTi and the output signal OUTj deviate by, for example, |i−j|times the period of the clock CLK, where i and j are natural numbers.

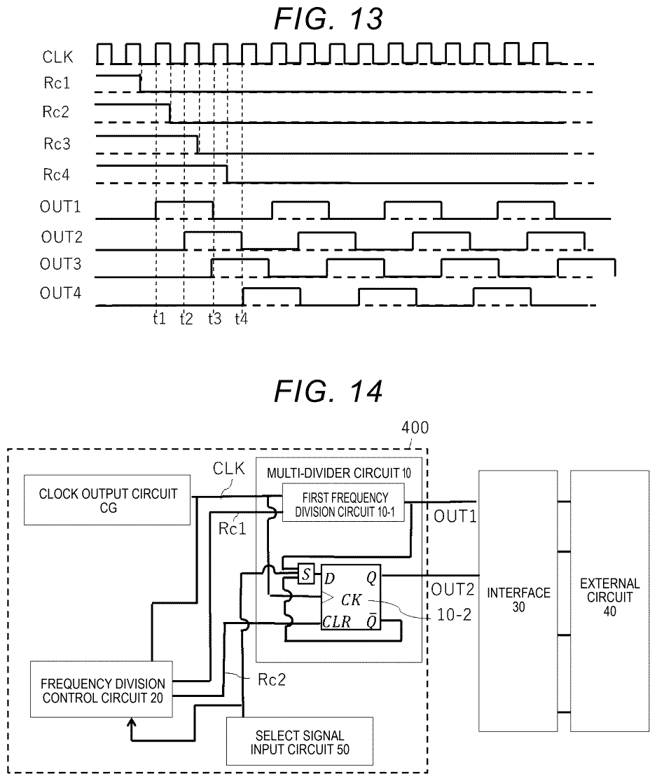

When n is 3 or more, the first rising edge time t1 of the output signal OUT1 is measured, the first rising edge time t2 of the output signal OUT2 is measured, the first rising edge time t3 of the output signal OUT3 is measured, . . . and the first rising edge time tn of the output signal OUTn is measured, the second rising edge time t(n +1) of the output signal OUT1 is measured, etc. In this manner, the rising edge time t1, t2, t3, etc. of clock CLK can be obtained (for example, see FIG. 13). The characteristic of the clock CLK can be evaluated by reproducing a waveform of the clock CLK from each rising edge time calculated for the plurality of output signals OUT1 to OUTn and then comparing the waveform with an ideal clock period. For example, a rising edge time of one output signal can be used as a reference to relatively measure a rising edge time of another output signal and compare the rising edge time with an ideal clock period. Specifically, when the number of output signals is n and m satisfies 1≤m<n, the output signal OUT(m+1) can be evaluated with the output signal OUTm as a reference, that is, (t(m+1)−tm) is measured.

These measurements can be repeated a plurality of times. Alternatively, not only the value t2-t1 between the output signals OUT1 and OUT2, but also the value t2′-t1′ illustrated in FIG. 5 can be used as one of the data for evaluating Jitter. In this manner, a statistical distribution of n-1 values (t2−t1, t3−t2, . . . and tn−t(n−1)) relatively evaluated for the n output signals can be obtained.

A standard deviation of a distribution of a statistical quantity of n−1 (t2−t1, t3−t2, . . . tn−t(n−1)) is Δj1, Δj2, . . . and Δj(n−1). The Jitter is evaluated as a whole of the multi-divider circuit 10 from a magnitude of variations in distribution of the statistical quantity of n−1 types of (t2−t1, t3−t2, . . . and tn−t(n−1)). For example, the variance Δj² and the standard deviation Δj of the multi-divider circuit 10 as a whole are evaluated by adding the variances of n−1 statistical quantities by Δj=[(Δj1)²+(Δj2)²+(Δj3)²+ . . . +(Δj(n−1))²]^{1/2}. The magnitude of the variations in the clock characteristics as a whole of the multi-divider circuit 10 is not limited to the above equation, and may be evaluated based on the variations in the statistical quantity obtained from the output signal of each frequency division circuit.

The statistical quantity obtained from the output signals of each frequency division circuit may be obtained by relatively evaluating each output signal with respect to a single output signal. For example, a rising edge time of each output signal may be evaluated by reference to the rising edge time t1 of the output signal OUT1. For example, with respect to the output signal OUTn, tn−t1 is obtained and the obtained value is compared with a value when an ideal clock having an ideal period (n−1 times the original clock period), and can also be used as one of the data for evaluating Jitter.

The measurement of the characteristics of the clock CLK can be performed as a statistical process. That is, instead of comparing Jitter of one pulse or the like, a distribution of Jitter for a large number of pulses may be obtained by obtaining each of the rising edge times t1, t2, t3, . . . of the clock CLK, and the distribution may be evaluated based on a spread (for example, standard deviation) of the distribution. The smaller the spread of distribution of the characteristics of the clock CLK, the more stable the quality of the clock CLK is, which is desirable.

With the clock modulation circuit 100, the frequency division control circuit 20 controls the start time of frequency division in the multi-divider circuit 10, so that a frequency of the clock CLK can be divided to a frequency that can be output from the interface 30 and the characteristics of the clock CLK can be measured externally with high accuracy.

Thus, even when the frequency of the clock CLK is so high that the signal cannot otherwise be output from the interface 30, the frequency of the clock CLK is divided to be reduced, so that the signal is modulated to a signal that can be measured by the external circuit 40 may be output. According to the present embodiment, it is possible to perform an off-chip measurement of a high-speed clock CLK.

In addition, in the example having the two frequency division circuits for frequency division by 2 illustrated in FIG. 5, with the two output signals OUT1 and OUT2, divided signals without losing information on the signal characteristics of the clock CLK are generated. That is, the amount of information is maintained by branching the frequency into the two output signals, instead of the frequency being ½. When the multi-divider circuit 10 has a frequency division circuit for frequency division by n, the amount of information can be maintained by branching a frequency into n output signals, instead of the frequency being 1/n.

The multi-divider circuit 10 in the present embodiment has at least two frequency division circuits. Even when the multi-divider circuit 10 has a frequency division circuit for frequency division by n, two or more frequency division circuits are provided, the clock characteristics can be estimated by measuring a time difference between a plurality of output signals. Further, since the multi-divider circuit 10 has two or more frequency division circuits, a decrease in amount of information due to a decrease in frequency by frequency division can be avoided, and the amount of information obtained on the characteristics of the clock CLK can be increased. For example, the decrease in amount of information obtained from the signal after division per unit time or per constant number of pulses of the clock CLK is avoided. However, when having a frequency division circuit for frequency division by n, it is desirable that the multi-divider circuit 10 has n or more frequency division circuits to measure the characteristics of the clock CLK without omission (comprehensively).

By increasing the amount of information obtained for the characteristics of the clock CLK, the number of measured samples may be increased when the characteristics of the clock CLK are to be statistically evaluated, so that accuracy of the statistical analysis is improved and accuracy of the estimation of the characteristics of the clock CLK is improved. Alternatively, a time required to obtain a sufficient number of samples can be reduced, and measurement with sufficient accuracy can be performed more efficiently.

Further, according to the present embodiment, since the multi-divider circuit 10 has a certain number of frequency division circuits, it is possible to estimate the rising edge time of the clock CLK without omission. Therefore, for example, even when frequency division by n is performed, n measurement quantities (samples) are obtained every n pulses of the clock CLK. On the other hand, when just one frequency division circuit is provided for frequency division by n in a comparative example, just one measurement quantity (sample) is obtained per n pulses of the clock CLK signal. However, in the present embodiment, the number of samples can be more than the number of pulses. Furthermore, it would be necessary to repeat the measurement n times in order to prepare the same number of samples when the comparative example (a single frequency division circuit) is adopted.

Specifically, in FIG. 5, the rising edge times of the output signals OUT1 and OUT2 correspond to the rising edge of the clock CLK at intervals of one. For example, the number of pulses of the measurement target in the external circuit 40 would be one-half the number of rising edges of the clock CLK for just the output signal OUT1. However, the number of rising edges obtained by combining the output signals OUT1 and OUT2, as in the present embodiment, is equal to the full number of rising edges in the clock CLK signal, and the rising edge time of the clock CLK can be estimated without omission.

With the clock modulation circuit 100 according to the present embodiment, the shift time of the frequency division start signal (Rc1 or Rc2) to the L-state deviates by the period of the clock CLK, so that the frequency division control circuit 20 can reliably control the times of the operations of the plurality of frequency division circuits. Further, the frequency division start signal (Rc1 or Rc2) is triggered by a falling edge of the clock CLK, and the frequency division circuit of the multi-divider circuit 10 is triggered by the rising edge of the clock CLK. As illustrated in FIG. 5, for example, a margin is generated between the times of the falling edge of the first frequency division start signal Rc1 and the rising edge of the output signal OUT1, and the frequency division operation can be stably controlled. The falling edge of the frequency division start signal (Rc1 or Rc2) and a trigger (rising edge of the clock) of the frequency division circuit in the multi-divider circuit 10 deviate by one-half the period of the clock CLK. For example, even when there is a time deviation less than one-half the period between the clock CLK input to the frequency division control circuit 20 and the clock CLK input to the multi-divider circuit 10, the rising edge of the output signal can be controlled at a desired time.

In some examples, frequency division start signals (Rc1 or Rc2) may be triggered by the rising edge of the clock CLK, and the frequency division circuit of the multi-divider circuit 10 may be triggered by the falling edge of the clock CLK.

### First Modification Example of First Embodiment

In FIGS. 7, 8A, 8B, and 9, a measurement flow for more accurately measuring characteristics of the clock CLK will be further described as a first modification example of the first embodiment.

FIG. 7 illustrates a flow by which the characteristics of the clock CLK can be measured with higher accuracy by adding to the flow illustrated in FIG. 6.

First, in step S210, the frequency division control circuit 20 is turned on. Here, the turning on is not limited to a case where the frequency division control circuit 20 is shifted from an off-state to an on-state, but also includes a case where the frequency division control circuit 20 is shifted from the on-state to the off-state once and then is shifted to the on-state.

Next, in step S220, the frequency division control circuit 20 shifts the first frequency division start signal Rc1 and the second frequency division start signal Rc2 to an L-state at the same time (with a time difference less than ¼ of a period of the clock CLK). Here, the operation of the frequency division control circuit 20 is different from the operations in steps 120 and 140 illustrated in FIG. 6, and this can be implemented by adding, for example, a switch to the frequency division start signal generation circuit 23 illustrated in FIG. 3 to output the first frequency division start signal Rc1 as the second frequency division start signal Rc2. By switching the switch, it is selected whether the second frequency division start signal Rc2 outputs the same signal as the first frequency division start signal Rc1 or outputs a signal triggered by a different bit sequence as illustrated in FIG. 4.

Subsequently, in step S230, the output signals OUT1 and OUT2 are output from the first frequency division circuit 10-1 and the second frequency division circuit 10-2. Although a phase difference between the output signals OUT1 and OUT2 is ideally zero, a phase difference between the output signals OUT1 and OUT2 may occur due to a Skew caused by a difference in distance of the signal transmission of the clock CLK input to the first frequency division circuit 10-1 and the second frequency division circuit 10-2, and the fluctuation in the signal characteristics derived from the internal configuration of the first frequency division circuit 10-1 and the second frequency division circuit 10-2.

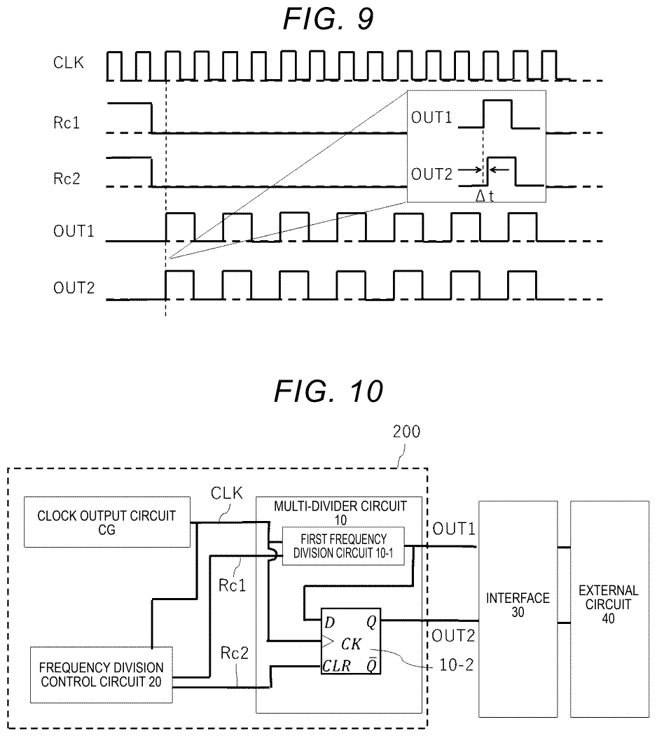

The output signals OUT1 and OUT2 are transmitted to the external circuit 40 via the interface 30. In step S240, the external circuit 40 measures a time difference Δt of the rising edges of the output signals OUT1 and OUT2 of which the frequency is divided and reduced. Although FIG. 9 illustrates the time difference Δt for a first pulse, the time difference Δt can be measured for each pulse.

In step S250, a phase difference between the output signals OUT1 and OUT2 is measured. The Skew caused by the difference in the distance of the signal transmission of the clock CLK input to the first frequency division circuit 10-1 and the second frequency division circuit 10-2, and the fluctuation in the signal characteristics derived from the internal configuration of the first frequency division circuit 10-1 and the second frequency division circuit 10-2 can be estimated. First, when Skew occurs, the Skew can be detected as an offset of a phase difference, such as a phase difference in which a phase of an output signal OUT2 is constantly delayed with respect to a phase of an output signal OUT1, for example, due to a fixed difference in length of the signal paths.

The phase difference due to the fluctuation in the signal characteristics derived from the internal configuration of the first frequency division circuit 10-1 and the second frequency division circuit 10-2 may be the portion that remains as a spread in the statistical distribution after the offset of the phase difference due to the Skew is removed (compensated). In step S250, a distribution of the phase difference due to the fluctuation of the signal characteristics derived from the internal configuration of the first frequency division circuit 10-1 and the second frequency division circuit 10-2 is estimated.

In step S260, the time t1, t2, etc. measured by the flow illustrated in steps S110 to S170 illustrated in FIG. 6 are corrected based on the Skew measured in step S250 and the fluctuation of the signal characteristics derived from the internal configuration of the first frequency division circuit 10-1 and the second frequency division circuit 10-2. For example, when a Skew value is obtained in step S250, the influence of the difference in the signal transmission path can be reduced by subtracting the delay corresponding to the Skew from the measurement results at the time t2 (or t2′) of the output signal OUT2 illustrated in FIG. 5.

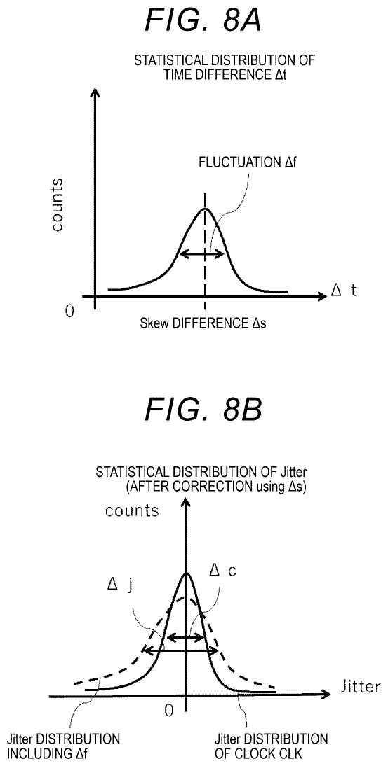

Here, an example of a method of correcting based on a measurement result of the time difference Δt will be described with reference to FIGS. 8A and 8B.

FIG. 8A illustrates an example of the measurement result of the time difference Δt. FIG. 8B illustrates an example of the measurement result of Jitter.

As illustrated in FIG. 8A, when the time difference Δt is measured, a distribution having a width of a fluctuation Δf of signal characteristics inside the multi-divider circuit 10 is obtained, centering around a Skew Δs in this example. The fluctuation Δf in this example is taken as a full width at half maximum (FWHM) of the distribution.

The estimation of the Jitter characteristics illustrated in FIG. 8B is performed by using the results of the estimation of the Skew Δs and the fluctuation Δf. First, the correction is performed for the times t1, t2, t1′, t2′, etc. illustrated in FIG. 5 from the Skew Δs. For example, when the output signal OUT2 is delayed from the output signal OUT1 by the Skew Δs, the time t2, t2′, etc. obtained from the output signal OUT2 are compared to the output signal OUT1 while subtracting the Skew Δs.

As a result of the correction using the Skew Δs, the Jitter distribution (illustrated by a dotted line) in FIG. 8B is obtained. The Jitter distribution has a width centered on zero, for example. The width Δj of the Jitter distribution is a FWHM.

Next, correction is performed based on the estimation result of the fluctuation Δf. The width Δj includes both the Jitter distribution of the clock CLK (the FWHM is Δc) and the effect of the fluctuation Δf. Therefore, (Δj)²=(Δc)²+(Δf)², and Δc=[(Δj)² (Δf)²]^{1/2}. In this manner, the width Δc of the Jitter distribution of the clock CLK can be estimated.

In the present modification example, the width Δc of the Jitter distribution of the clock CLK is estimated based on the Skew Δs and the fluctuation Δf.

Here, a method of estimating the characteristics of the clock CLK when the number of output signals is three or more (n is three or more) will be described. The output signals will be OUT1, OUT2, OUT3, and OUT4. The time difference Δt of each rising edge of the output signals OUT1 and OUT2 is measured as illustrated in FIG. 9. In addition, a difference of each rising edge time between the output signals OUT2 and OUT3 is measured, and a difference of each rising edge time between the output signals OUT3 and OUT4 is measured.

In this manner, a Skew Δs and a fluctuation Δf are separately obtained as between the output signals OUT1 and OUT2, as between the output signals OUT2 and OUT3, and as between the output signals OUT3 and OUT4. Since Skew depends on a path difference, correction can be separately performed for each path to obtain a statistical distribution of the Jitter. In this manner, the fluctuations (Δf1, Δf2, Δf3) are respectively obtained for between the output signals OUT1 and OUT2, the output signals OUT2 and OUT3, and the output signals OUT3 and OUT4. From these component fluctuations, a fluctuation in the signal characteristics derived from the internal configuration as a whole of the multi-divider circuit 10 may be estimated. For example, the fluctuation Δf=[(Δf1)²+(Δf2)²+(Δf3)²]^{1/2} is evaluated as a fluctuation in the signal characteristics derived from the internal configuration as a whole of the multi-divider circuit 10.

Further, the rising edge time of each output signal is measured relatively and, for example, the value Δj1 is obtained by evaluating the output signal OUT2 with the output signal OUT1 as a reference. The value Δj2 is obtained by evaluating the output signal OUT3 with the output signal OUT2 as a reference, and the value Δj3 is obtained by evaluating the output signal OUT4 with the output signal OUT3 as a reference. The value Δj, which is an index of variations of the clock characteristics as a whole of the multi-divider circuit 10, is evaluated as Δj=[(Δj1)²+(Δj2)²+(Δj3)²]^{1/2}.

The width Δc of the Jitter distribution of the clock CLK itself can be estimated as Δc=[(Δj)²−(Δf)²]^{1/2}. In this manner, the influence on the clock characteristics such as Jitter by the multi-divider circuit 10 can be reduced, and the value Δc can be evaluated as the characteristic of the clock CLK itself.

FIG. 9 illustrates a timing chart of the operation corresponding to the flow described in FIG. 7.

First, the first frequency division start signal Rc1 and the second frequency division start signal Rc2 are shifted to an L-state at the same time by using a falling edge of the clock CLK as a trigger. The first frequency division circuit 10-1 and the second frequency division circuit 10-2 start the operations at the same time.

Since the first frequency division start signal Rc1 and the second frequency division start signal Rc2 are in the L-state, the output signals OUT1 and OUT2 start to output frequency-divided signals at the same time by using a rising edge of the clock CLK as a trigger.

Ideally, since the rising edge of the clock CLK at the same time is the trigger, there should be no difference in phase between the output signals OUT1 and OUT2. However, strictly, the time at which the clock CLK reaches the first frequency division circuit 10-1 and the second frequency division circuit 10-2 will typically be different due to a path difference for the clock signal between the clock output circuit CG and the first frequency division circuit 10-1 and the second frequency division circuit 10-2. When the signal path between the clock output circuit CG and the second frequency division circuit 10-2 is longer, the phase of the output signal OUT2 is delayed from the phase of the output signal OUT1. In this manner, a time difference of Δt may occur between the rising edges of the output signals OUT1 and OUT2.

In addition, Δt may also include a phase difference due to the fluctuation in the signal characteristics derived from the internal configuration of the first frequency division circuit 10-1 and the second frequency division circuit 10-2.

According to the clock modulation method according to the present modification example, the time difference Δt of the rising edges of the output signals OUT1 and OUT2 can be measured, and the Skew and the like may be estimated, so that measurement accuracy of the characteristic of the clock CLK can be further improved.

In the clock modulation method according to the first embodiment (FIG. 6), the output signals OUT1 and OUT2 may include fluctuations in signal characteristics of the clock CLK itself, as well as the fluctuation in signal characteristics derived from the path difference in signal transmission and the internal configuration of the first frequency division circuit 10-1 and the second frequency division circuit 10-2. In the first embodiment, when the fluctuation in the signal characteristics derived from the path difference in signal transmission and the internal configuration of the first frequency division circuit 10-1 and the second frequency division circuit 10-2 are sufficiently small, the characteristics of the clock CLK can be estimated directly.

With the clock modulation method according to the present modification example, even when there is a large path difference in signal transmission and a large Skew, the Skew may be estimated in advance by the flow illustrated in FIG. 7. When measuring Jitter or the like in the flow illustrated in FIG. 6, the influence of the Skew can be canceled out, and the characteristics of the clock CLK itself can be estimated with higher accuracy.

In addition, as the circuit configuration inside the multi-divider circuit 10 is complicated (the number of circuit elements increases), there is a concern that the fluctuation in the signal characteristics due to the internal configuration in the multi-divider circuit 10 may be increased. According to the present modification example, as illustrated in FIG. 8A, the fluctuation of the signal characteristics based on the internal configuration of the multi-divider circuit 10 can be estimated as the fluctuation Δf. By performing correction based on the fluctuation Δf with respect to the distribution of the measurement result of Jitter, the original Jitter distribution of the clock CLK can be estimated. Therefore, the signal characteristics of the clock CLK can be measured with higher accuracy.

### Second Embodiment

FIG. 10 is an example of a circuit configuration of a clock modulation circuit 200 according to a second embodiment. Description of some of parts common to the clock modulation circuit 100 according to the first embodiment will be omitted.

In the second embodiment, a circuit configuration of the multi-divider circuit 10 is different from the circuit configuration of the multi-divider circuit 10 of the first embodiment. The multi-divider circuit 10 has at least two frequency division circuits. The first frequency division circuit 10-1 is a frequency division circuit for frequency division by n (n is a natural number and n≥2). The second frequency division circuit 10-2 is a D flip-flop with reset. Although FIG. 10 illustrates an example in which the multi-divider circuit 10 has two frequency division circuits, the multi-divider circuit 10 may have three or more frequency division circuits (the third and subsequent frequency division circuits can also be D flip-flops with reset).

The output signal OUT1 of the first frequency division circuit 10-1 is input to the data input terminal D of the second frequency division circuit 10-2.

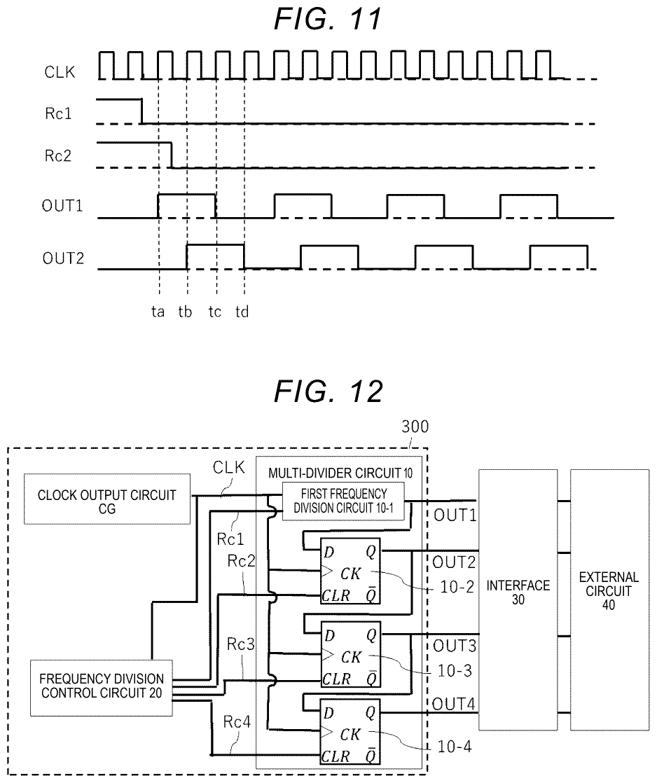

A shift time of the frequency division start signals Rc1 and Rc2 to an L-state is, for example, as illustrated in FIG. 11. In the same manner as with the output signal OUT1, the output signal OUT2 is also a signal obtained by dividing a frequency of the clock CLK by n, and a rising edge time is delayed by a period of the clock CLK from a rising edge time of the output signal OUT1 by controlling the frequency division start signals Rc1 and Rc2.

The operation of the clock modulation circuit 200 according to the second embodiment will be described with reference to FIG. 11. For simplicity, an example in which the first frequency division circuit 10-1 is a circuit for frequency division by 4 will be described, but the present disclosure is not limited thereto.

First, the frequency division control circuit 20 controls a shift time of the first frequency division start signal Rc1 and the second frequency division start signal Rc2 to the L-state, in the same manner as in the first embodiment. For example, the first frequency division start signal Rc1 and the second frequency division start signal Rc2 are shifted to the L-state by using a falling edge of the clock CLK as a trigger.

The output signal OUT1 is shifted to an H-state at a time when the first frequency division start signal Rc1 is in the L-state and the clock CLK rises (time ta). In the example of frequency division by 4 on the first frequency division circuit 10-1, a frequency of the output signal OUT1 is ¼ of the frequency of the clock CLK.

Next, the second frequency division start signal Rc2 is shifted to an L-state at a time delayed by the period of the clock CLK from the first frequency division start signal Rc1. The output signal OUT2 is shifted to an H-state at a time when the second frequency division start signal Rc2 is in an L-state and the clock CLK rises, to reflect the state of the output signal OUT1, which is input to the data input terminal D (time tb).

Next, the H-state of the output signal OUT1 is maintained for a period that is twice the period of the clock CLK, and then the output signal OUT1 is shifted to an L-state (time tc). Here, at the rising edge of the clock CLK at the time tc, the output signal OUT2 is not shifted to an L-state. This is because, although not illustrated in FIG. 11, the rising edge of the clock CLK input to the second frequency division circuit 10-2 and the falling edge of the output signal OUT1 are not strictly at the same time, and the rising edge of the clock CLK input to the second frequency division circuit 10-2 is earlier. The falling edge of the output signal OUT1 is also originally triggered by the rising edge of the clock CLK, but since the output signal OUT1 is a signal generated through the first frequency division circuit 10-1, the transmission path of the signal is longer than the clock CLK, which is directly input to the second frequency division circuit 10-2, and the transmission takes time.

That is, in FIG. 11, the rising edge of the clock CLK and the falling edge of the output signal OUT1 appear to have no time difference, but the output signal OUT1 is in an H-state at the rising edge time of the clock CLK which is input to the second frequency division circuit 10-2, so the output signal OUT2 also maintains the H-state at the time tc.

Finally, the H-state of the output signal OUT2 is maintained for a period that is twice the period of the clock CLK, and then the output signal OUT2 is shifted to an L-state (time td).

According to the clock modulation circuit 200 according to the second embodiment, the circuit configuration inside the multi-divider circuit 10 is simplified, so that the fluctuation of the signal characteristics derived from the circuit configuration inside the multi-divider circuit 10 can be reduced, and accuracy of the estimation of the characteristics of the clock CLK can be further improved.

For comparison, when a multi-divider circuit 10 has two frequency division circuits for frequency division by n, the second frequency division circuit 10-2 may also include a plurality of flip-flops to operate for frequency division by n. As the number of circuit elements such as flip-flops provided in the multi-divider circuit 10 is large, there is concern that the fluctuation in the signal characteristics may be increased.

However, according to the clock modulation circuit 200 according to the second embodiment, a signal obtained by dividing the frequency of the clock CLK by n may be output as the output signal OUT2 and the second frequency division circuit 10-2 may include only one D flip-flop, so that the number of circuit elements provided in the multi-divider circuit 10 can be reduced. Although the first frequency division circuit 10-1 is a frequency division circuit for frequency division by n, the effect of reducing the number of circuit elements in the present embodiment increases as n increases.

When n≥3 for the first frequency division circuit 10-1 for frequency division by n, the multi-divider circuit 10 has at least two frequency division circuits, and thus it is possible to estimate the characteristics of the clock CLK such as Jitter from the measurement results of the output signals OUT1 and OUT2 after frequency division.

### Third Embodiment

FIG. 12 is an example of a circuit configuration of a clock modulation circuit 300 according to a third embodiment. FIG. 13 is a timing chart illustrating an example of an operation of the clock modulation circuit 300 illustrated in FIG. 12. Description of some of parts common to the clock modulation circuit 100 according to the first embodiment will be omitted.

In the clock modulation circuit 300 according to the third embodiment, a circuit configuration of the multi-divider circuit 10 is different from the first embodiment. The first frequency division circuit 10-1 is a frequency division circuit for frequency 4-division. Although the example of the frequency division by 4 is described, the present disclosure is not limited thereto. Although the example in which the multi-divider circuit 10 has four frequency division circuits is described, the multi-divider circuit 10 may have two or more frequency division circuits.

The output signal OUT1 of the first frequency division circuit 10-1 is input to the data input terminal D of a flip-flop which is the second frequency division circuit 10-2. The output signal OUT2 of the second frequency division circuit 10-2 is input to the data input terminal D of a flip-flop which is the third frequency division circuit 10-3. The output signal OUT3 of the third frequency division circuit 10-3 is input to the data input terminal D of a flip-flop which is the fourth frequency division circuit 10-4.

The first frequency division start signal Rc1, the second frequency division start signal Rc2, the third frequency division start signal Rc3, and the fourth frequency division start signal Rc4 are input from the frequency division control circuit 20. The first frequency division start signal Rc1, the second frequency division start signal Rc2, the third frequency division start signal Rc3, and the fourth frequency division start signal Rc4 are controlled by switching based on the clock CLK. For example, the bit sequences (X3, X2, X1) illustrated in FIG. 4 are respectively controlled as the first frequency division start signal Rc1, the second frequency division start signal Rc2, the third frequency division start signal Rc3, and the fourth frequency division start signal Rc4 by using the states of 001, 010, 011, and 100 as triggers.

The operation of the clock modulation circuit 300 will be described with reference to FIG. 13.

The first frequency division start signal Rc1, the second frequency division start signal Rc2, the third frequency division start signal Rc3, and the fourth frequency division start signal Rc4 are shifted by the period of the clock CLK from an H-state to an L-state by the frequency division control circuit 20. The second frequency division start signal Rc2 is shifted to an L-state at a time delayed by a period of the clock CLK from the first frequency division start signal Rc1. The third frequency division start signal Rc3 is shifted to an L-state at a time delayed by the period of the clock CLK from the second frequency division start signal Rc2. The fourth frequency division start signal Rc4 is shifted to an L-state at a time delayed by the period of the clock CLK from the third frequency division start signal Rc3.

When the first frequency division start signal Rc1 is in the L-state, the first frequency division circuit 10-1 performs a frequency division operation, and the output signal OUT1 is output. The output signal OUT1 rises by using a rising edge of the clock CLK as a trigger. A period of the output signal OUT1 is four times a period of the clock CLK.

A rising edge of the output signal OUT2 is delayed by the period of the clock CLK from the rising edge of the output signal OUT1. A rising edge of the output signal OUT3 is delayed from the rising edge of the output signal OUT1 by twice the period of the clock CLK. A rising edge of the output signal OUT4 is delayed from the rising edge of the output signal OUT1 by three times the period of the clock CLK.

The rising edge time will be further described with reference to FIG. 12.

The output signal OUT1 is input to the data input terminal D of the second frequency division circuit 10-2. A signal waveform of the output signal OUT2 in the L-state is shifted to the H-state when the second frequency division start signal Rc2 is in the L-state, the data input terminal D receives the input in the H-state, and the rising edge of the clock CLK is input to the clock input terminal CK. The second frequency division start signal Rc2 is shifted to the L-state at a time between the rising edge of the output signal OUT1 and a rising edge of a next pulse of a pulse that is a trigger for the rising edge of the output signal OUT1. The output signal OUT2 of the second frequency division circuit 10-2 rises at a rising edge of a pulse next to the pulse that is a trigger for the rising edge of the output signal OUT1. In this manner, the rising edge time of the output signal OUT2 is delayed by the period of the clock CLK from the rising edge time of the output signal OUT1.

In the same manner, the rising edge of the output signal OUT3 of the third frequency division circuit 10-3 to which the output signal OUT2 is input to the data input terminal D is delayed by the period of the clock CLK from the rising edge of the output signal OUT2. A rising edge of the output signal OUT4 of the fourth frequency division circuit 10-4 to which the output signal OUT3 is input to the data input terminal D is delayed by the period of the clock CLK from the rising edge of the output signal OUT3.

With reference to FIG. 13, when the output signals OUT1, OUT2, OUT3, and OUT4 after frequency division by 4 are combined, the rising edge time of the clock CLK can be estimated from the rising edge of the combined output signal without omission. That is, by preparing four output signals instead of the clock signal frequency being reduced to ¼ its original frequency, a decrease in amount of information to be measured can be avoided.

In the clock modulation circuit 100 according to the first embodiment, when the multi-divider circuit 10 has a frequency division circuit for frequency 4-division, four frequency division circuits for frequency division by 4 are provided. The frequency division circuit for frequency division by 4 can be implemented by connecting, for example, two flip-flops, and in the first embodiment, for example, 2×4=8 flip-flops would be used. It is considered that increasing the number of elements in the multi-divider circuit 10 tends to increase the fluctuation in the signal characteristics of the multi-divider circuit 10.

With the clock modulation circuit 300 according to the third embodiment, additional fluctuation in the signal characteristics caused by the internal configuration of the multi-divider circuit 10 can be avoided, and the accuracy of the estimation of the characteristics of the clock CLK can be further improved. When the first frequency division circuit 10-1 is a frequency division circuit for frequency division by n, D flip-flops are provided as the second frequency division circuit 10-2, . . . and the n-th frequency division circuit 10-n, so that the characteristics of the clock CLK can be measured without omission while limiting the number of internal circuit elements.

The clock modulation circuit 300 according to the third embodiment performs the frequency 4-division, by providing, for example, two flip-flops in the first frequency division circuit 10-1. The second frequency division circuit 10-2, the third frequency division circuit 10-3, and the fourth frequency division circuit 10-4 are replaced with just one flip-flop, so that a total number of flip-flops is 5. As compared with the first embodiment, it is possible to reduce the number of elements necessary for the multi-divider circuit 10. Therefore, the fluctuation in the signal characteristics caused by the internal configuration of the multi-divider circuit 10 can be reduced, and the accuracy of the estimation of the characteristics of the clock CLK can be further improved.

### Fourth Embodiment

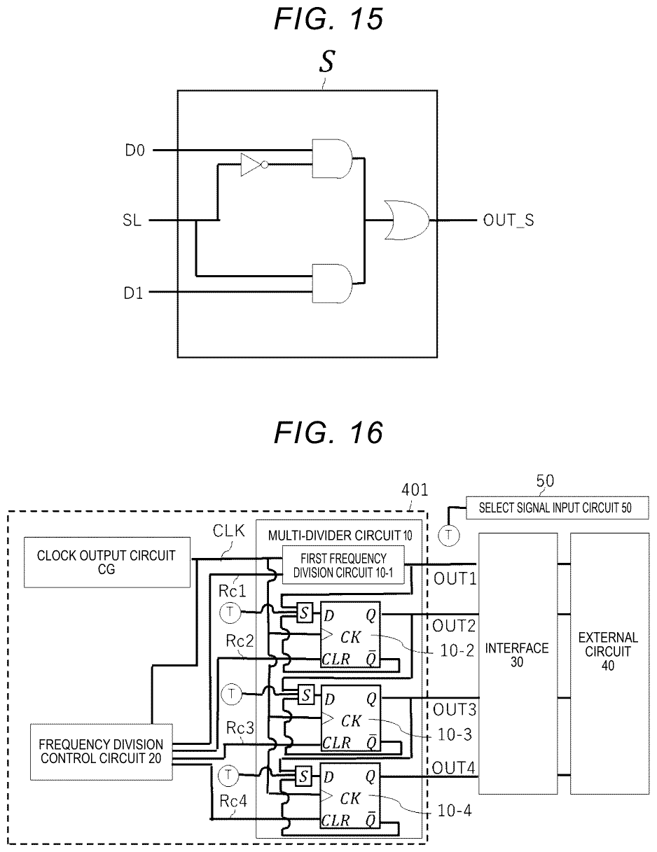

FIG. 14 is an example of a circuit configuration of a clock modulation circuit 400 according to a fourth embodiment. FIG. 15 is an example of a circuit configuration of a select circuit S, which is also depicted in FIG. 14. Description of some of parts common to the clock modulation circuit 200 according to the second embodiment will be omitted.

The fourth embodiment is different from the second embodiment in that the select circuit S is provided in the multi-divider circuit 10. Although an example in which the multi-divider circuit 10 has two frequency division circuits is described, the multi-divider circuit 10 may have more frequency division circuits. The first frequency division circuit 10-1 is a frequency division circuit for frequency division by n (where n≥2). The second frequency division circuit 10-2 is, for example, a D flip-flop with reset.

First, the select circuit S connected to the second frequency division circuit 10-2 will be described. The select circuit S is connected to the data input terminal D of the flip-flop of the second frequency division circuit 10-2. The select circuit S has three input terminals. The select circuit S includes a terminal D0 to which the output signal OUT1 from the first frequency division circuit 10-1 is input, a terminal SL to which an output from a select signal input circuit 50 is input, and a terminal D1 to which the output from an inversion output terminal Q* of the second frequency division circuit 10-2 is input (see FIG. 15).

The select signal input circuit 50 may be provided in the same chip as the multi-divider circuit 10 in the clock modulation circuit 400, but is not limited thereto. The select signal input circuit 50 outputs a signal controlled be either an H-state (1) or an L-state (0).

An operation of the select circuit S will be described with reference to FIG. 15. The terminal D0 of the select circuit S is a terminal to which the output signal OUT1 in FIG. 14 is input. The terminal SL is a terminal to which the output of the select signal input circuit 50 in FIG. 14 is input. The terminal D1 is a terminal to which the output from an inversion output terminal Q* of the second frequency division circuit 10-2 in FIG. 14 is input.

The select circuit S outputs the signal input from one of the terminals D0 or D1 as an output signal OUT_S based on an input signal at the terminal SL. For example, when the input from the terminal SL is in the L-state (0), the input from the terminal D0 is output as the output signal OUT_S. When the input from the terminal SL is in the H-state (1), the input from the terminal D1 is output as the output signal OUT_S.

An example of the operation of the select circuit S connected to the second frequency division circuit 10-2 will be described with reference to FIG. 14.

First, the operation when the input from the select signal input circuit 50 is in an L-state (0) will be described. At this time, the output signal OUT1 is input to the data input terminal D of the flip-flop which is the second frequency division circuit 10-2. Therefore, in the same manner as in FIG. 10 illustrating the clock modulation circuit 200 according to the second embodiment, a signal of which a rising edge time deviates from a rising edge time of the output signal OUT1 is output as the output signal OUT2. A phase of the output signals OUT1 and OUT2 deviates by a period of the clock CLK, so that it is possible to estimate characteristics of the clock CLK (for example, Jitter).

When the input from the select signal input circuit 50 is in the H-state (1), the output from the inversion output terminal Q* is input to the data input terminal D of the second frequency division circuit 10-2. Therefore, the second frequency division circuit 10-2 performs a frequency division operation based on the second frequency division start signal Rc2. The output signal OUT2 is a signal obtained by dividing a frequency of the clock CLK by 2. For example, as illustrated in FIG. 9, the first frequency division start signal Rc1 and the second frequency division start signal Rc2 are shifted to the L-state (0) at the same time, and the time difference Δt caused by the path difference in signal transmission can be measured by comparing the rising edges of the output signals OUT1 and OUT2. The output signals OUT1 and OUT2 do not necessarily need to have the same frequency since the time difference Δt can be measured as long as the rising edge triggers are the same rising edge triggers of the clock CLK.

That is, by controlling whether the input from the select signal input circuit 50 is in the L-state (0) or the H-state (1), the operation of measuring Δt and the operation of measuring the characteristics of the clock CLK can be switched.

When the input from the select signal input circuit 50 is in the L-state (0), the frequency division control circuit 20 counts the pulses of the clock CLK, and the falling edge times of the first frequency division start signal Rc1 and the second frequency division start signal Rc2 deviate.

When the input from the select signal input circuit 50 is in the H-state (1), the frequency division control circuit 20 controls the first frequency division start signal Rc1 and the second frequency division start signal Rc2 to rise at the same time. The frequency division control circuit 20 and the select signal input circuit 50 perform switching of the operation in cooperation with each other, as described above. A configuration in which the frequency division control circuit 20 and the select signal input circuit 50 are linked can include a circuit in which the second frequency division start signal Rc2 is switched to a state of the first frequency division start signal Rc1 in the frequency division control circuit 20. The operation of switching the second frequency division start signal Rc2 to the state of the first frequency division start signal Rc1 is controlled in response to an input from the select signal input circuit 50. For example, the select circuit selects a signal between the first frequency division start signal Rc1 and the second frequency division start signal Rc2 in response to the input from the select signal input circuit 50, and the signal after the selection is again the second frequency division start signal Rc2.

According to the clock modulation circuit 400, the fluctuation of the signal waveform caused by the internal configuration of the multi-divider circuit 10 can be prevented, and the accuracy of the estimation of the characteristics of the clock CLK can be improved. Further, by providing the select circuit S, a mode of measuring time difference Δt and a mode of measuring the characteristics of the clock CLK can be switched. By measuring the time difference Δt due to the path difference in the signal transmission and the fluctuation of the signal waveform caused by the internal configuration of the multi-divider circuit 10, the accuracy of the estimation of the characteristics of the clock CLK can be further improved.

In the third embodiment, the second frequency division circuit 10-2 (and the third frequency division circuit 10-3 through the n-th frequency division circuit 10-n, when n≥3) can be replaced with a flip-flop. By reducing the number of elements provided in the circuit, the fluctuation of the signal waveform caused by the internal configuration of the multi-divider circuit 10 is avoided.

By providing the select circuit S, the phase difference (that is, the rising edge time of the pulse) of the output signals OUT1 and OUT2 can be controlled, and the measurement of the time difference Δt can be performed. For comparison, the configuration illustrated in FIG. 10 has an advantage in that the number of elements provided in the multi-divider circuit 10 is further reduced (the select circuit S is not essential), but the phase difference between the output signals OUT1 and OUT2 is, for example, the length of the period of the clock CLK.

When the output from the inversion output terminal Q* is input to the data input terminal D of the flip-flop which is the second frequency division circuit 10-2 by the select circuit S, the phase difference between the output signals OUT1 and OUT2 is controllable by control of the frequency division control circuit 20. Therefore, the clock modulation circuit 400 can measure the time difference Δt.

In the fourth embodiment, the number of elements provided in the multi-divider circuit 10 can be reduced, and the influence on the signal waveform by the multi-divider circuit 10 can be corrected. Therefore, the accuracy of the estimation of the characteristics of the clock CLK can be further improved.

The select signal input circuit 50 is provided in the clock modulation circuit 400 depicted in FIG. 14, but is not limited thereto. For example, as illustrated in FIG. 16 illustrating a clock modulation circuit 401 according to a modification example, the select signal input circuit 50 may be provided in a chip different from the clock modulation circuit 400.

Further, as illustrated in FIG. 16, when a third frequency division circuit 10-3 or a fourth frequency division circuit 10-4 is provided, a select circuit S can also be provided in each, and the signal from the select signal input circuit 50 is transmitted via a point T.

In FIG. 16, for the third frequency division circuit 10-3 and the fourth frequency division circuit 10-4, by controlling whether the input from the select signal input circuit 50 is in an L-state (0) or an H-state (1), the operation of measuring Δt and the operation of measuring the characteristics of the clock CLK can be selectively used.

### Fifth Embodiment

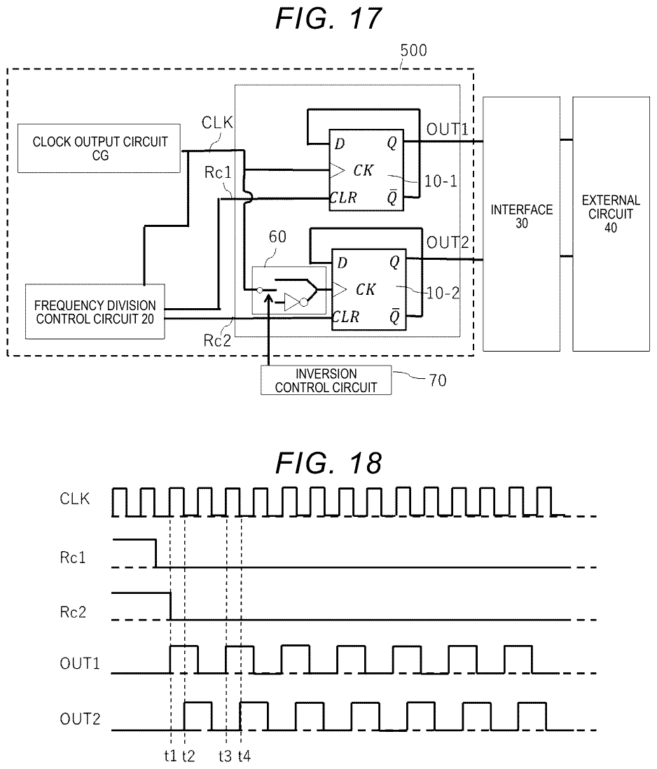

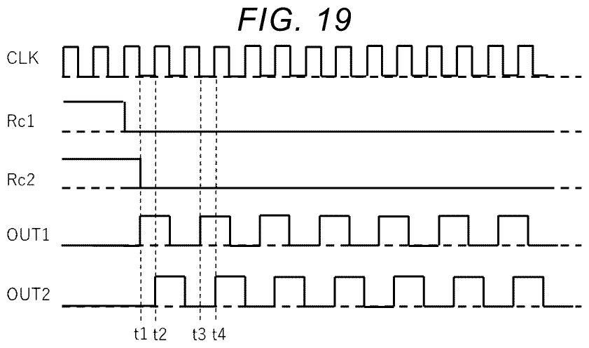

FIG. 17 is an example of a circuit configuration of a clock modulation circuit 500 according to a fifth embodiment. FIGS. 18 and 19 are timing charts illustrating an example of an operation of the clock modulation circuit 500. Description of some of parts common to the clock modulation circuit 100 according to the first embodiment will be omitted.

The fifth embodiment is different from the first embodiment in that an inversion switch circuit 60 is provided in the multi-divider circuit 10. Although an example in which the first frequency division circuit 10-1 and the second frequency division circuit 10-2 are frequency division circuits for frequency division by 2 is described, the present disclosure is not limited thereto. Although the example in which the multi-divider circuit 10 has two frequency division circuits is described, the multi-divider circuit 10 may have more than two frequency division circuits.

The inversion switch circuit 60 is provided between the clock output circuit CG and at least one of the frequency division circuits provided in the multi-divider circuit 10 of the clock modulation circuit 400. In FIG. 17, the inversion switch circuit 60 is provided between the second frequency division circuit 10-2 and the clock output circuit CG. The inversion switch circuit 60 has an inversion circuit and a switch.

The inversion switch circuit 60 is connected to an inversion control circuit 70. The inversion control circuit 70 controls switching of the switch in the inversion switch circuit 60. Although the inversion control circuit 70 is not depicted as being in the clock modulation circuit 500 in FIG. 17, the clock modulation circuit 500 and the inversion control circuit 70 may be formed on the same chip in other examples.

FIG. 17 illustrates an example of a circuit configuration of the inversion switch circuit 60. The switch of the inversion switch circuit 60 switches whether a signal of the clock CLK passes through the inversion circuit. The operation when the signal of the clock CLK does not pass through the inversion circuit is the same as that in the clock modulation circuit 100 illustrated in FIG. 2, and thus the description thereof will be omitted. For example, signal characteristics such as Jitter of the clock CLK can be estimated.

Next, the operation when the signal of the clock CLK passes through the inversion circuit will be described with reference to FIG. 18. In the first frequency division circuit 10-1, a rising edge of the clock CLK is a trigger, while for the second frequency division circuit 10-2, a falling edge of the clock CLK is effectively a trigger in FIG. 18.

The second frequency division start signal Rc2 is delayed in falling edge by half a period of the clock CLK as compared with the first frequency division start signal Rc1. The output signal OUT1 is shifted to an H-state (1) at a time when the first frequency division start signal Rc1 is in an L-state and the clock CLK rises. Subsequently, the output signal OUT2 is shifted to an H-state (1) at a time when the second frequency division start signal Rc2 is in an L-state and the clock CLK falls. The rising edge times of the output signals OUT1 and OUT2 are different by half a length of the period of the clock CLK.

Here, waveforms of the first frequency division start signal Rc1 and the second frequency division start signal Rc2 are different from those in FIG. 4, and this can be implemented by a circuit having the following configuration. For example, the frequency division control circuit 20 illustrated in FIG. 3 is triggered by a falling edge of a clock, but by further providing another frequency division control circuit that is triggered by a rising edge of the clock, and thus, the second frequency division start signal Rc2 in FIG. 18 can be output.

The fifth embodiment may also be implemented by a circuit having the following configuration. In FIG. 4, the bit sequence (X3, X2, X1) is switched at every period of the clock CLK. For example, by further adding the clock CLK itself to the bit sequence, a bit sequence that is switched in order of 0000, 0001, 0010, 0011, . . . 1111 for each half period of the clock CLK can be generated. When a bit indicating a state of the clock CLK is denoted by C, a 4-bit bit sequence X3 X2 X1 C is formed.

For example, the frequency division control circuit 20 having a 4-input, 16-output decoder shifts the first frequency division start signal Rc1 to an L-state for the bit sequence 0010, and shifts the second frequency division start signal Rc2 to an L-state for the bit sequence 0011, and the like. The clock CLK is shifted to an H-state (1) after a time equal to half a period of the clock CLK elapses from the shift of the first frequency division start signal Rc1 to an L-state, and the second frequency division start signal Rc2 is shifted to an L-state (refer to the waveforms of X3, X2, and X1 in FIG. 4 and the clock CLK).

A difference between the time t1 of the rising edge of the output signal OUT1 and the time t2 of the rising edge of the output signal OUT2 corresponds to a pulse width of the clock CLK. In the same manner, by measuring the time t3 of the next rising edge of the output signal OUT1 and the time t4 of the next rising edge of the output signal OUT2, the pulse width of the clock CLK can be estimated.

FIG. 19 illustrates an example in which the inversion switch circuit 60 is provided in the first frequency division circuit 10-1. The output signal OUT1 is triggered by a falling edge of the clock CLK. On the other hand, the output signal OUT2 is triggered by a rising edge of the clock CLK.

By measuring a time difference between the time t1 and the time t2 illustrated in FIG. 19, a duration of a valley between pulses of the clock CLK can be measured.

Therefore, in the clock modulation circuit 500, a duty cycle, which is one of the characteristics of the clock CLK, can be estimated. By switching the switch of the inversion switch circuit 60, a mode for measuring Jitter and a mode for measuring a duty cycle among the characteristics of the clock CLK can be switched.

With the clock modulation circuit 500, the duty cycle of the clock CLK can also be estimated, and thus the characteristics of the clock CLK can be more reliably evaluated.

Also, with the configuration of the fifth embodiment, as described in the clock modulation method according to the first modification example of the first embodiment, the Skew Δs and the fluctuation Δf can be estimated to further improve the accuracy of the characteristics of the clock CLK.

According to a semiconductor device of at least one of the first to fifth embodiments described above, the multi-divider circuit 10 having the plurality of frequency division circuits can avoid a decrease in the amount of information of the signal after the frequency of the clock CLK is divided for analysis, and the characteristics of the clock CLK can be measured with higher accuracy.

Although the shift to the H-state and the shift to the L-state are described in the above description, the H-state and the L-state may be switched. For example, the frequency division operation may start when the first frequency division start signal Rc1 is shifted to an H-state, and the frequency division operation may start when the first frequency division start signal Rc1 is shifted to an L-state. Further, whether to be triggered by the rising edge or the falling edge of the pulse may be selected as appropriate. Although the times of the rising edges of the output signals OUT1, OUT2, etc. are compared in the above examples, the times of the falling edges of the output signals OUT1, OUT2, etc. may be compared in other examples.

As described above, the embodiments are described with reference to specific examples. The present disclosure is not limited to these specific examples. That is, the embodiment includes examples in which a person skilled in the art makes design changes as appropriate, as long as the specific examples include the features of the embodiment. Each element, the disposition of each element, the material, the condition, the shape, the size, and the like in each of the specific examples described above are not limited to the examples and may be changed as appropriate.

In addition, the elements and aspects provided in each of the embodiments described above may be combined as much as possible from a technical point of view, and a combination of these embodiments is also included in the scope of the present disclosure as long as the combination incorporates the features of the described embodiments.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

### Appendix 1

A clock modulation circuit including:
a clock output circuit;
a multi-divider circuit that has a plurality of frequency division circuits to which a clock is input from the clock output circuit and which divides the clock; and
a frequency division control circuit that controls a start time of frequency division of each of the plurality of frequency division circuits and controls a phase difference between at least one pair of output signals of the plurality of frequency division circuits based on a period of the clock.

### Appendix 2

A clock modulation circuit including:
a clock output circuit;
a multi-divider circuit to which a clock is input from the clock output circuit and which has a first frequency division circuit and a second frequency division circuit; and
a frequency division control circuit that transmits a first frequency division start signal to the first frequency division circuit and transmits a second frequency division start signal to the second frequency division circuit.

### Appendix 3

The clock modulation circuit according to Appendix 2, in which an absolute value of a time difference of a rising edge or a falling edge of the first frequency division start signal and the second frequency division start signal is ¾ or more and 5/4 or less of a period of the clock.

### Appendix 4

The clock modulation circuit according to Appendix 2, in which the frequency division control circuit receives the clock, and controls a time difference of a rising edge or a falling edge of the first frequency division start signal and the second frequency division start signal.

### Appendix 5

The clock modulation circuit according to Appendix 2,
in which the frequency division control circuit includes
   a bit sequence generation circuit to which the clock is input, and
   a frequency division start signal generation circuit that converts a signal of m bits (m is a natural number and m≥2) output by the bit sequence generation circuit into the first frequency division start signal and the second frequency division start signal.

### Appendix 6

The clock modulation circuit according to Appendix 5,
in which the frequency division start signal generation circuit includes a decoder.

### Appendix 7

The clock modulation circuit according to Appendix 5,
in which for the natural number m, 2^{m}−1 is equal to or more than the number of frequency division circuits provided in the multi-divider circuit.

### Appendix 8

The clock modulation circuit according to Appendix 2,
in which the first frequency division circuit and the second frequency division circuit are connected in parallel to the clock output circuit.

### Appendix 9

The clock modulation circuit according to Appendix 2,
in which an output of the first frequency division circuit is input to the second frequency division circuit.

### Appendix 10

The clock modulation circuit according to Appendix 9,
in which the second frequency division circuit is a flip-flop.

### Appendix 11

The clock modulation circuit according to Appendix 2, further including:
a select circuit to which an output of the first frequency division circuit and an inversion output of the second frequency division circuit are input,
in which an output of the select circuit is input to the second frequency division circuit.

### Appendix 12

The clock modulation circuit according to Appendix 2,
in which an inversion switch circuit that receives an input from a switch and inverts the clock in accordance with a state of the switch is provided between the second frequency division circuit and the clock output circuit.

### Appendix 13

The clock modulation circuit according to Appendix 1 or 2,
in which the multi-divider circuit has at least n frequency division circuits for frequency division by n (n ≥2).

### Appendix 14

A clock modulation method for a clock modulation circuit that includes a clock output circuit which outputs a clock, a frequency division control circuit, a first frequency division circuit, and a second frequency division circuit, the method including:
transmitting a first frequency division start signal, which is output from the frequency division control circuit, to the first frequency division circuit;
outputting a first output signal, which is obtained by the first frequency division circuit dividing a frequency of the clock;
transmitting a second frequency division start signal, which is output from the frequency division control circuit, to the second frequency division circuit; and
outputting a second output signal, which is obtained by the second frequency division circuit dividing the frequency of the clock.

### Appendix 15

The clock modulation method according to Appendix 14,
in which the frequency division control circuit outputs the second frequency division start signal in which an absolute value of a time difference of a rising edge or a falling edge is ¾ or more and 5/4 or less of a period of the clock, as compared with the first frequency division start signal.

### Appendix 16

The clock modulation method according to Appendix 14,
in which the frequency division control circuit receives the clock, generates a bit sequence, and outputs the first and second frequency division start signals having a rising edge or a falling edge in accordance with a different value of the bit sequence.

### Appendix 17

The clock modulation method according to Appendix 14,
in which a third frequency division start signal which is output from the frequency division control circuit is transmitted to the first frequency division circuit, and
a fourth frequency division start signal which is output from the frequency division control circuit and in which a time difference of a rising edge or a falling edge is ¼ or less of a period of the clock as compared with the third frequency division start signal is transmitted to the second frequency division circuit.

### Appendix 18

The clock modulation method according to Appendix 17,
in which the first frequency division circuit that receives the third frequency division start signal outputs a third output signal, and
the second frequency division circuit that receives the fourth frequency division start signal outputs a fourth output signal in which a phase difference with the third output signal is ¼ or more and ¾ or less of the period of the clock.

### Appendix 19

The clock modulation method according to any one of Appendices 14 to 18,
in which a time of a rising edge or a falling edge of the first output signal and the second output signal is measured to estimate a characteristic of the clock.

### Appendix 20

The clock modulation method according to Appendix 18,
in which a time of a rising edge or a falling edge of the third output signal and the fourth output signal is measured,
a Skew due to a difference in signal transmission path and a signal fluctuation due to a circuit configuration of the clock modulation circuit are estimated, and
a time of a rising edge or a falling edge of the first output signal and the second output signal is measured to estimate a characteristic of the clock.

What is claimed is:

1. A clock modulation circuit, comprising:
a clock output circuit configured to output a clock signal;
a multi-divider circuit that has a plurality of frequency division circuits to which the clock signal from the clock output circuit is input, each frequency division circuit being configured to frequency divide the clock signal; and
a frequency division control circuit configured to control a frequency division start time for each of the frequency division circuits and control a phase difference between output signals of at least one pair of frequency division circuits in the plurality of frequency division circuits based on a period of the clock signal.

2. A clock modulation circuit, comprising:
a clock output circuit configured to output a clock signal;
a multi-divider circuit to which the clock signal is input from the clock output circuit, the multi-divider circuit having a first frequency division circuit and a second frequency division circuit, each of which being configured to perform frequency division on the clock signal; and
a frequency division control circuit configured to transmit a first frequency division start signal to the first frequency division circuit and a second frequency division start signal to the second frequency division circuit.

3. The clock modulation circuit according to claim 2, wherein an absolute value of a time difference of a rising edge or a falling edge of the first frequency division start signal and the second frequency division start signal is in a range of ¾ to 5/4 of the period of the clock signal.

4. The clock modulation circuit according to claim 2, wherein the frequency division control circuit receives the clock signal and controls a time difference of a rising edge or a falling edge of the first frequency division start signal and the second frequency division start signal.

5. The clock modulation circuit according to claim 2, wherein the frequency division control circuit includes:
a bit sequence generation circuit to which the clock signal is input, and
a frequency division start signal generation circuit that converts a signal of m bits (where m≥2) output by the bit sequence generation circuit into the first frequency division start signal and the second frequency division start signal.

6. The clock modulation circuit according to claim 2, wherein the first frequency division circuit and the second frequency division circuit are connected to the clock output circuit in parallel.

7. The clock modulation circuit according to claim 2, wherein an output of the first frequency division circuit is input to the second frequency division circuit.

8. The clock modulation circuit according to claim 2, further comprising:
a select circuit to which an output of the first frequency division circuit and an inverted output of the second frequency division circuit are input, wherein
an output of the select circuit is input to the second frequency division circuit.

9. The clock modulation circuit according to claim 2, wherein an inversion switch circuit that receives an input from a switch and inverts the clock signal in accordance with a state of the switch is between the second frequency division circuit and the clock output circuit.

10. A clock modulation method for a clock modulation circuit, the method comprising:
transmitting a first frequency division start signal from a frequency division control circuit to a first frequency division circuit that frequency divides a clock signal;
outputting a first output signal from the first frequency division circuit, the first output signal being a frequency divided clock signal;
transmitting a second frequency division start signal from the frequency division control circuit to a second frequency division circuit that frequency divides the clock signal; and
outputting a second output signal from the second frequency division circuit, the second output signal being a frequency divided clock signal.

11. The clock modulation method according to claim 10, wherein the second frequency division start signal is output from the frequency division control circuit with an absolute value of a time difference of a rising edge or a falling edge as compared to the first frequency division start signal is in a range of ¾ to 5/4 of a period of the clock signal.

12. The clock modulation method according to claim 10, wherein
the frequency division control circuit outputs a third frequency division start signal to the first frequency division circuit, and
the frequency division control circuit outputs a fourth frequency division start signal to the second frequency division circuit, and
a time difference of a rising edge or a falling edge of the fourth frequency division start signal as compared to the third frequency division start signal is ¼ or less of a period of the clock signal.

13. The clock modulation method according to claim 12, wherein
the first frequency division circuit outputs a third output signal after receiving the third frequency division start signal,
the second frequency division circuit outputs a fourth output signal after receiving the fourth frequency division start signal, and
a phase difference between the fourth output signal and the third output signal is in a range of ¼ to ¾ of the period of the clock signal.

14. The clock modulation method according to claim 13, wherein
a time of a rising edge or a falling edge of the third output signal and the fourth output signal is measured by an external circuit, and
a Skew value is estimated from the measured times of the rising edge or the falling edge of the third output signal and fourth output signal, the Skew value being associated with a difference in clock signal transmission path to the first and second frequency division circuits.

15. The clock modulation method according to claim 14, wherein a signal fluctuation value associated with circuit configurations is estimated from the measured times of the rising edge or the falling edge of the third output signal and fourth output signal.

16. The clock modulation method according to claim 15, wherein a time of a rising edge or a falling edge of the first output signal and the second output signal is measured by the external circuit to estimate a characteristic of the clock signal.

17. The clock modulation method according to claim 10, wherein a time of a rising edge or a falling edge of the first output signal and the second output signal is measured by an external circuit to estimate a characteristic of the clock signal.

18. The clock modulation method according to claim 17, wherein the external circuit receives the first and second output signals via an interface circuit.

19. The clock modulation method according to claim 18, wherein the clock signal has a frequency higher than a frequency the interface circuit can transmit to the external circuit.

20. The clock modulation method according to claim 10, wherein
the first and second output signals are output to an external circuit via an interface circuit, and
the clock signal has a frequency higher than a frequency the interface circuit can transmit to the external circuit.
